(19) United States
(12) Patent Application Publication
(10) Pub. No.: US 2026/0107401 A1
(43) Pub. Date: Apr. 16, 2026

(54) VIDEO PROCESSING EQUIPMENT COVER WITH INTEGRATED DISPLAY

(71) Applicant: Ross Video Limited, Iroquois (CA)

(72) Inventors: Donald Mark Sizemore, Virginia Beach, VA (US); A. Matthew Zimmer, Virginia Beach, VA (US); C. Jason Williams, Chesapeake, VA (US); Desmond Ambrose, Ottawa, ON (CA); J. Todd Riggs, Lakeland, FL (US); Troy English, Ottawa, ON (CA); Jonathan Pannaman, Grantsboro, NC (US); Joshua Ashcraft, Nashville, TN (US)

(21) Appl. No.: 19/104,625

(22) PCT Filed: Aug. 28, 2023
(86) PCT No.: PCT/CA2023/051136

§ 371 Date: Feb. 18, 2025

Related U.S. Application Data
(60) Provisional application No. 63/401,836, filed on Aug. 29, 2022.

(51) Int. Cl. H05K 7/14

(52) U.S. Cl. CPC H05K 7/1422; H05K 7/1492

(57) ABSTRACT

A cover for video processing equipment may include one or more integrated displays. A rack-mount chassis for such equipment may be mountable to an equipment rack, and be designed to accommodate video cards that support processing of video input signals to generate video output signals. A cover for an external face of the rack-mount chassis at which the rack-mount chassis is mountable to the equipment rack may include a control unit, a connector to provide a local connection between the control unit and the video cards, and a display coupled to the control unit to provide a control interface that enables control of the video processing equipment by an operator.

### CROSS-REFERENCE TO RELATED APPLICATION

This application is related to, and claims priority of, United States Provisional Ser. No. 63/401,836 , filed on Aug. 29, 2022, the entire contents of which are incorporated herein by reference.

### FIELD

The present disclosure relates generally to video processing equipment, and in particular to an equipment cover that has an integrated display.

### BACKGROUND

Video equipment control and monitoring typically involve a workstation or other device that is located remotely from the equipment that is to be controlled and/or monitored. For example, video equipment may be rack-mounted equipment in a server room, and one or more network-connected workstations may be located in a different room or at different premises.

Although remote control and monitoring is convenient in many scenarios and applications, latency in network communications between equipment and remote workstations, monetary cost of workstations and associated cabling, time involved in setup and configuration of workstations and associated cabling, and physical distance between workstations and equipment in the case of equipment setup or troubleshooting for example, are among potential challenges presented by conventional monitoring and control approaches.

### SUMMARY

According to embodiments disclosed herein, a cover for video processing equipment such as a video router, which may be implemented as an integrated “front door” workstation for example, provides a local control surface or system that is directly connected to the equipment. Such a control surface or system may support control, monitoring, diagnostics, and/or other functions or features in a multipurpose panel display. An integrated touch panel control, diagnostic, and monitoring display may be provided for a video routing and processing platform, for example.

One aspect of the present disclosure relates to video processing equipment comprising: a rack-mount chassis that is mountable to an equipment rack, the rack-mount chassis comprising a housing to accommodate a plurality of video cards that support processing of video input signals to generate video output signals; and a cover for an external face of the rack-mount chassis at which the rack-mount chassis is mountable to the equipment rack, the cover comprising a control unit, a connector to provide a local connection between the control unit and the plurality of video cards, and a display coupled to the control unit to provide a control interface that enables control of the video processing equipment by an operator.

Another aspect of the present disclosure relates to a cover for an external face, of a rack-mount chassis for video processing equipment, at which the rack-mount chassis is mountable to an equipment rack, the cover comprising: an integrated control unit; a connector to provide a local connection between the integrated control unit and a plurality of video cards of the rack-mount chassis that support processing of video input signals to generate video output signals; and an integrated display, coupled to the integrated control unit, to provide a control interface that enables control of the video processing equipment by an operator.

Another aspect of the present disclosure relates to a method comprising: providing a rack-mount chassis, for video processing equipment, that is mountable to an equipment rack, the rack-mount chassis comprising a housing to accommodate a plurality of video cards that support processing of video input signals to generate video output signals; and providing a cover for an external face of the rack-mount chassis at which the rack-mount chassis is mountable to the equipment rack, the cover comprising a control unit, a connector to provide a local connection between the control unit and the plurality of video cards, and a display coupled to the control unit to provide a control interface that enables control of the video processing equipment by an operator.

Another aspect of the present disclosure relates to a method comprising: providing an integrated control unit integrated with a cover for an external face of a video processing equipment rack-mount chassis at which the rack-mount chassis is mountable to an equipment rack; providing a connector to provide a local connection between the integrated control unit and a plurality of video cards of the rack-mount chassis that support processing of video input signals to generate video output signals; and providing an integrated display integrated with the cover, the display being coupled to the integrated control unit, to provide a control interface that enables control of the video processing equipment by an operator.

Other aspects and features of embodiments of the present invention will become apparent to those ordinarily skilled in the art upon review of the following description.

### BRIEF DESCRIPTION OF THE DRAWINGS

Examples of embodiments of the invention will now be described in greater detail with reference to the accompanying drawings.

FIG. 1 illustrates an example of video equipment.

FIG. 2 is a block diagram illustrating an example video card just prior to being mated with a backplane.

FIG. 3 is an isometric view of an example video card.

FIG. 4 illustrates a partially exploded view of the example video card of FIG. 3.

FIGS. 5A and 5B are isometric views of an example video equipment rack-mount chassis.

FIGS. 5C-5G include front, left, top, right, and rear views of an example video equipment rack-mount chassis according to an embodiment.

FIG. 6 illustrates an example of a video equipment rack-mount chassis with a front cover according to one embodiment, mounted in an equipment rack.

FIG. 7 illustrates the example video equipment rack-mount chassis in FIG. 6 with the front cover open.

FIG. 8 is a block diagram illustrating an example cover according to an embodiment.

FIG. 9 is a block diagram illustrating, more generally, an example rack-mount chassis.

FIG. 10 is a block diagram illustrating another example rack-mount chassis that is also operable with one or more external devices.

FIGS. 11-19 are representations of example Graphical User Interface (GUI) screens that may be presented on a cover display in some embodiments.

### DETAILED DESCRIPTION

For illustrative purposes, specific example embodiments will now be explained in greater detail below in conjunction with the figures.

The embodiments set forth herein represent information sufficient to practice the claimed subject matter. Upon reading the following description in light of the accompanying figures, those of sufficient skill will understand the concepts of the claimed subject matter and will recognize applications of these concepts not particularly addressed herein. It should be understood that these concepts and applications fall within the scope of the disclosure and the accompanying claims.

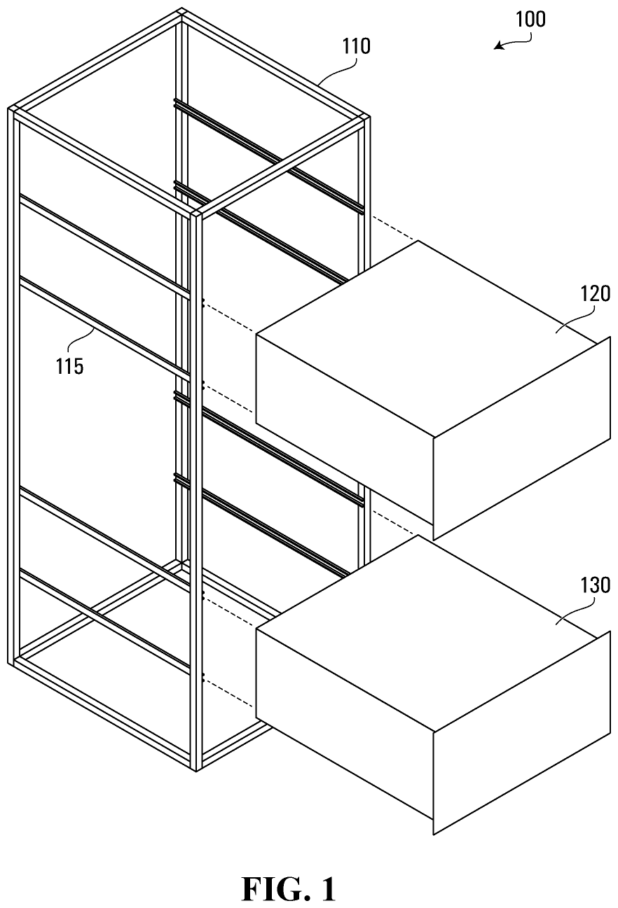

FIG. 1 illustrates an example of video equipment 100.

In the example shown, the video equipment 100 includes an equipment rack 110 and one or more rack-mount chassis, two of which are shown at 120, 130.

An equipment rack may be open at the sides and top as shown in FIG. 1, or at least partially enclosed. An enclosed equipment rack may also be referred to as a cabinet. Components 115 in FIG. 1 are intended to represent optional slides or members to support rack-mount chassis 120, 130 or structural beams to stabilize an equipment rack, which may be provided in some embodiments.

A rack-mount chassis 120, 130 may also or instead be referred to as a rack-mount unit or module, or a rack-mount frame, for example, and is a functional module or component that may implement, provide, or support any of various features or functions. In the case of video equipment, a rack-mount chassis 120, 130 may consist of, or at the very least include, a rack-mount chassis that provides or supports video processing, such as video routing.

Equipment racks and a rack-mount chassis may be provided in any of various physical sizes. For example, equipment racks may have different physical dimensions in one or more of height, width, and depth in different equipment installations, to accommodate different types, numbers, or sizes of rack-mount chassis. Rack-mount chassis 120, 130 for installation in an equipment rack may be of the same or different types or sizes. An equipment rack 100 may include different sizes of the same type of rack-mount chassis, such as rack-mount chassis of different sizes such as different “RU” sizes or with different physical dimensions in one or more of height, width, and depth. An equipment rack 100 may also or instead include different types of rack-mount chassis such as one or more video router rack-mount chassis and one or more rack-mount chassis that provide other types of video processing.

Each rack-mount chassis 120, 130 includes one or more electronic cards or boards. Electronic cards carried by a rack-mount chassis for video processing equipment at least include video cards, which may support processing of not only video signals, but possibly combined signals such as audio/video signals and data/video signals, audio signals that are related to video signals, and/or data signals that may, for example, include metadata related to video signals or audio/video signals. A video card in a rack-mount chassis for video processing equipment provides at least video processing features or functions, but is not necessarily limited only to processing video signals.

Although it is expected that video cards in any individual rack-mount chassis provide the same video processing features or functions for respective sets of input signals, it is possible that a rack-mount chassis may include different types of video cards. Video processing equipment and a rack-mount chassis for such equipment are not in any way limited only to video processing features. For example, a rack-mount chassis for video processing equipment may include one or more electronic cards that provide or support features other than video processing, and/or other components such as one or more power supplies, one or more cooling fans, etc.

Similarly, an equipment rack 100 may include different types of rack-mount chassis 120, 130, and certainly different equipment racks may include different types of rack-mount chassis.

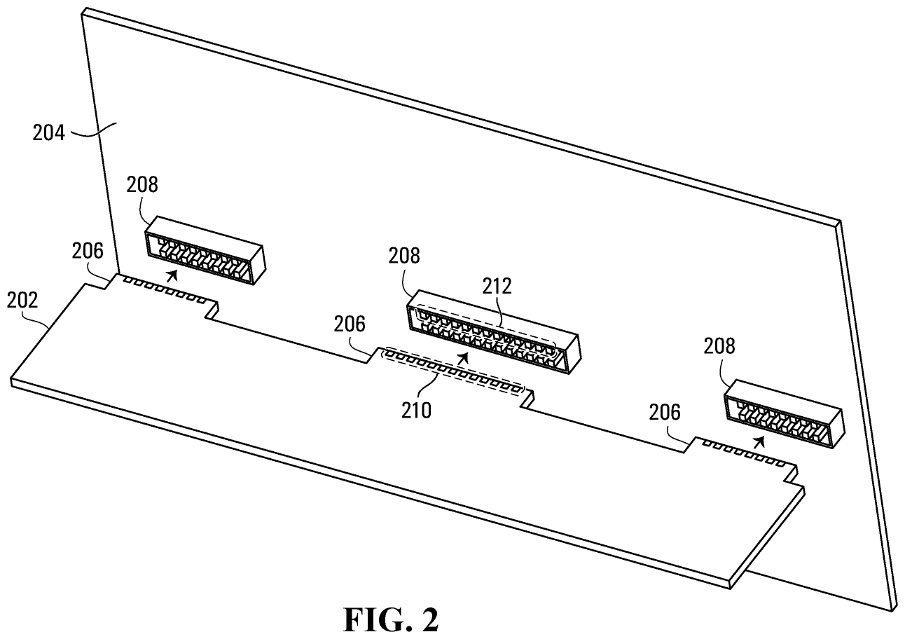

The video cards in a rack-mount chassis may be arranged, connected, and retained in the rack-mount chassis in any of various ways. FIG. 2 is a block diagram illustrating an example video card 202 just prior to being mated with a backplane 204 of a rack-mount chassis. The video card 202 in this example includes three projecting tongues 206, each of which is to be received or “seated” in a respective connector 208. Each connector 208 is mechanically and electrically connected to the backplane 204. Each tongue 206 includes a plurality of electrically conductive contact pads 210 that are to physically abut against corresponding electrically conductive connector contacts 212 in respective connector 208 when a tongue 206 is seated in a connector 208. The purpose of the contact pads 210 on each tongue 206 and corresponding contacts 212 of each connector 208 is to electrically connect signals between the video card 202 and the backplane 204 when the pads and connector contacts physically abut against each other.

FIG. 2 is an example, and variations are possible. For example, a backplane or other connection board or panel may, and in most expected implementations will, include connectors for more than one video card and possibly other types of electronic cards. One type of connector for mating with a tongue is shown, but other types of connectors, on either or both of a backplane and a video card, may be provided in addition to or instead of the connectors and tongues shown in FIG. 2. There may be more or fewer than three backplane and tongue connectors in other embodiments. Video cards are primarily of interest for the present disclosure, but a rack-mount chassis may also include other types of cards to be coupled to the same backplane as video cards, in a similar or different way using similar and/or different types of connectors.

Regarding connector types, the present disclosure is not in any way restricted to the example shown in FIG. 2 or elsewhere in the drawings. Tongues with conductive contact pads and mating connectors may be common for certain types of electronic cards, but connectors need not include conductive contact pads on tongues, or connectors to receive such tongues and mate with such contact pads. For example, optical interfaces or interfaces for other types of non-electrical signals may be provided to operatively couple or connect video cards and/or other types of electronic cards to a backplane or other internal panel or network within a rack-mount chassis.

In the view shown in FIG. 2, the video card is oriented horizontally. Video cards, and/or other types of cards, may instead be oriented vertically in a rack-mount chassis. Different rack-mount chassis may include video cards that are oriented differently. For example, an equipment rack or different equipment racks may include a rack-mount chassis with one or more cards oriented horizontally and a rack-mount chassis with one or more cards oriented vertically. It is also possible that an individual equipment rack (or one or more chassis) may include both one or more horizontally oriented cards and one or more cards vertically oriented cards.

A backplane or other connection panel in a rack-mount chassis may itself be oriented vertically or horizontally. Although vertical orientation to enable electronic cards to be installed from the front or rear of a rack-mount chassis is perhaps most common, vertical orientation to enable electronic cards to be installed from either or both sides of a rack-mount chassis, and horizontal orientation to enable electronic cards to be installed from a top and/or a bottom of a rack-mount chassis are possible.

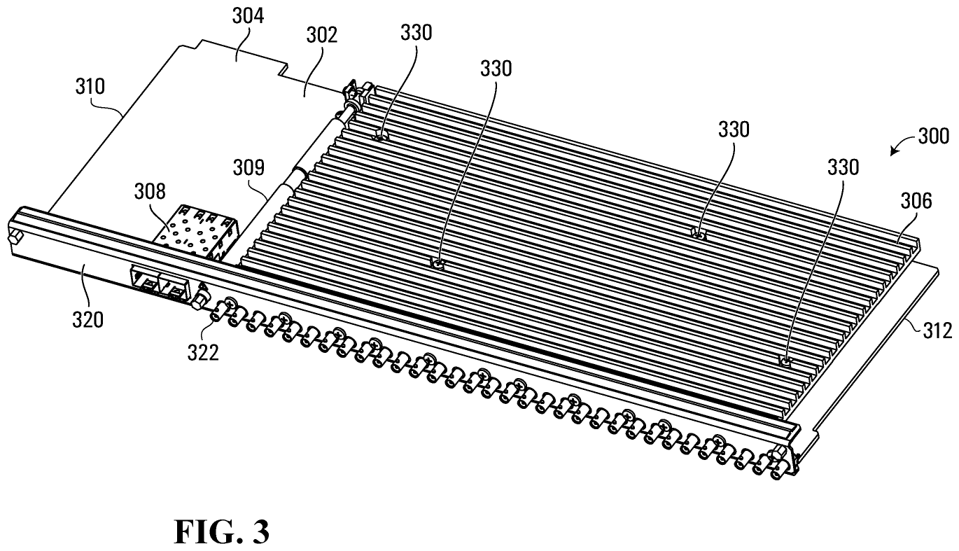

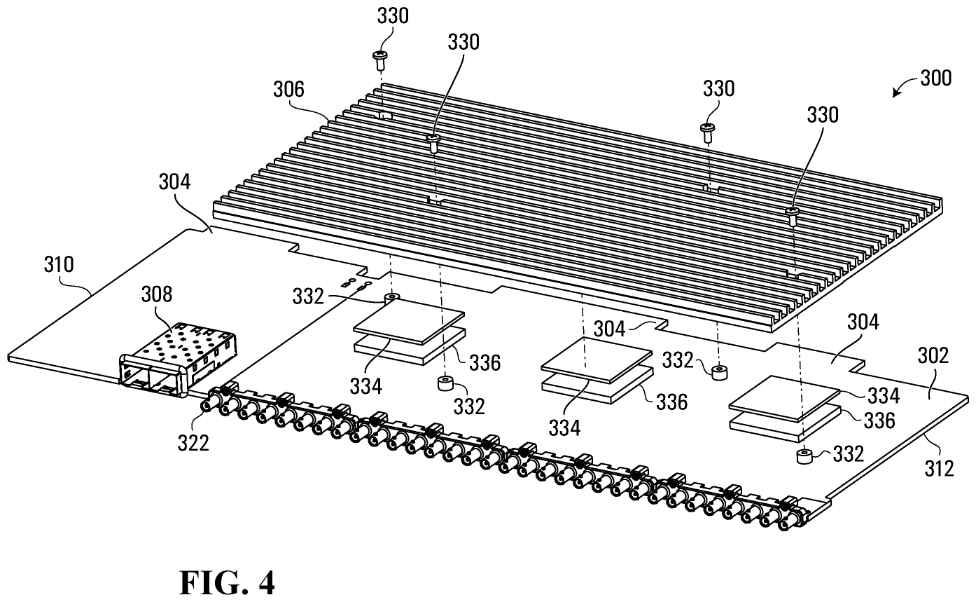

FIG. 2 provides a very general representation of a video card. FIG. 3 is an isometric view of another example video card, and FIG. 4 illustrates a partially exploded view of the example video card of FIG. 3. The example video card 300 includes a printed circuit board 302, with sides or edges 310, 312 at the left and right in the view shown, and connectors 304 (at a rear side or edge in the view shown) through which the printed circuit board can be connected to off-board components. In an embodiment, the connectors 304 mate with mating connectors in a rack-mount chassis, as shown by way of example in FIG. 2, when the video card 300 is installed.

In the example shown, the video card 300 has a connector housing 308, a retainer element 309 which releasably retains the card in its installed position, and a heat spreader 306 attached with screws 330. The screws 330 pass through bores in the heat spreader 306 and engage posts 332 which are attached to the printed circuit board, as shown in FIG. 4. A cover plate 320 is attached to the video card 300, and additional connectors 322 are also provided, to enable external components to be connected to the electronic card. In the example, shown, there are thirty-two connectors 322, to provide sixteen video input ports and sixteen video output ports. This is an example only, and embodiments are not limited to any particular number of video input signals or output signals.

Underneath the heat spreader 306, electronic components 336 are mounted to the printed circuit board 302. Although three components 336 are shown, there may be fewer or more components in an actual implementation, and these components could include multiple components of the same type or components of different types. In order to avoid congestion in the drawing, three components of the same shape and size are shown, solely for the purposes of illustration. Thermal pads 334 facilitate heat transfer from the components 336 to the heat spreader 306 for dissipation. Such heat transfer need not be dependent upon the thermal pads 334, as there would still be some heat transfer from the components 336 to the heat spreader 306 through air, but in some embodiments the thermal pads may improve thermal conduction between the components and the heat spreader.

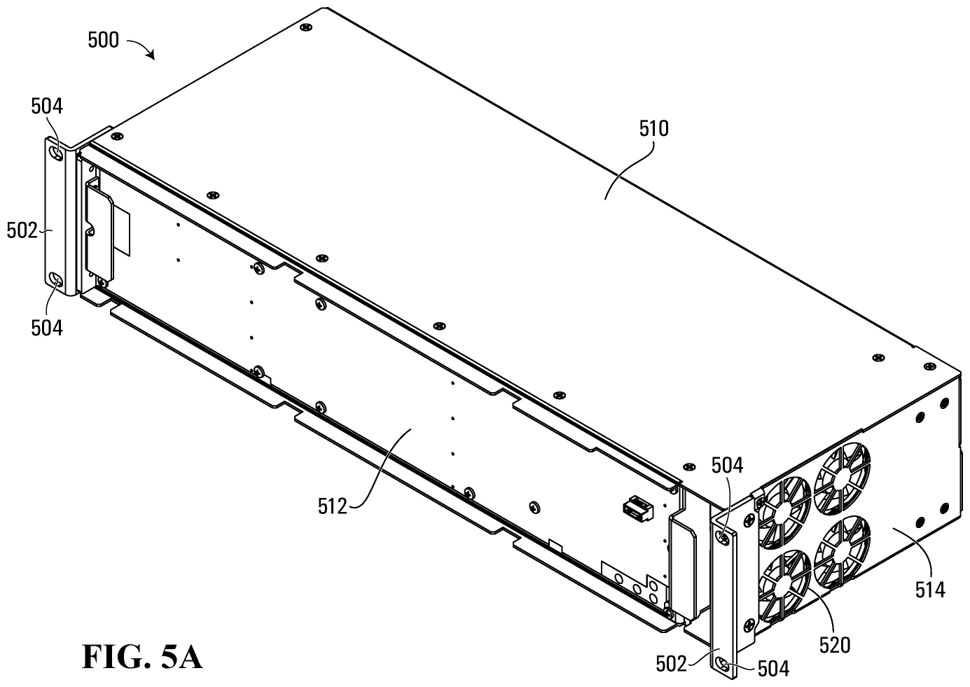

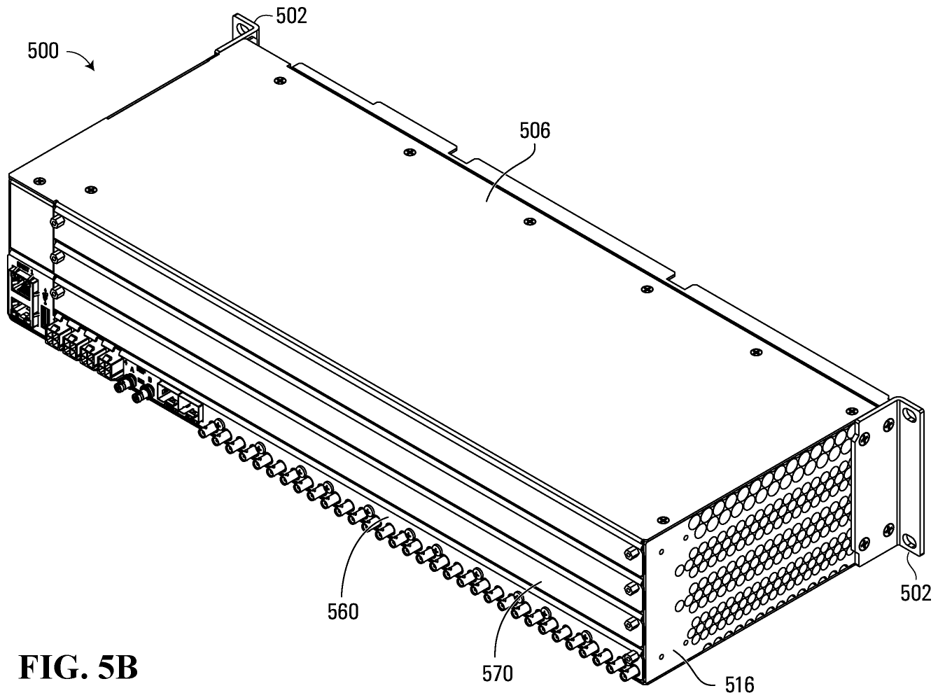

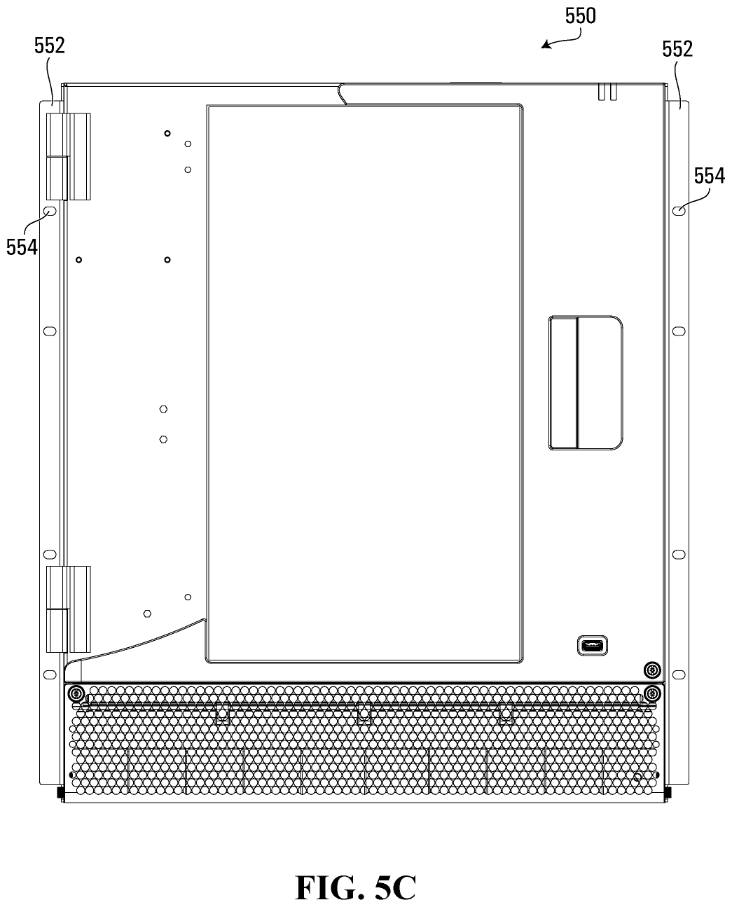

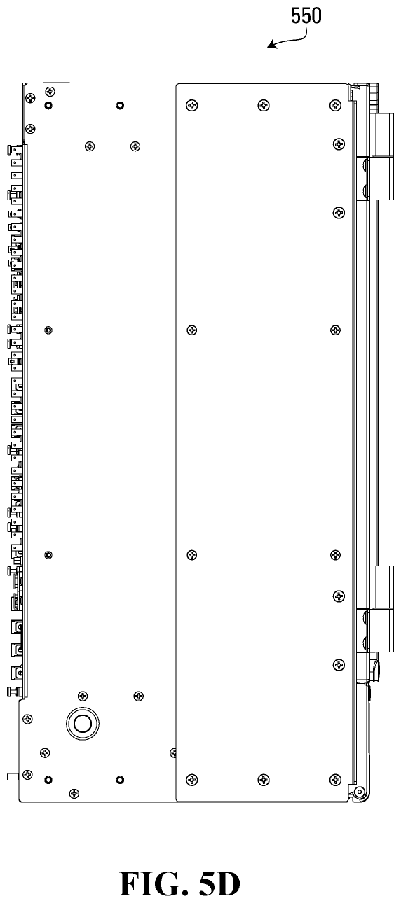

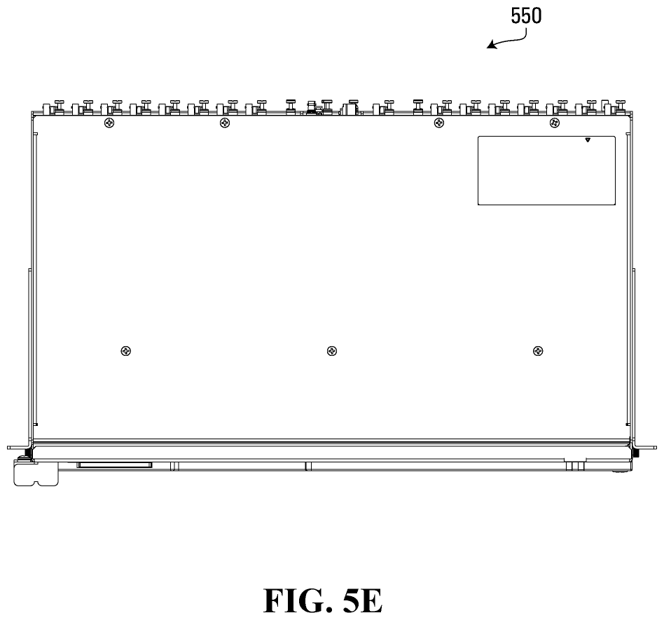

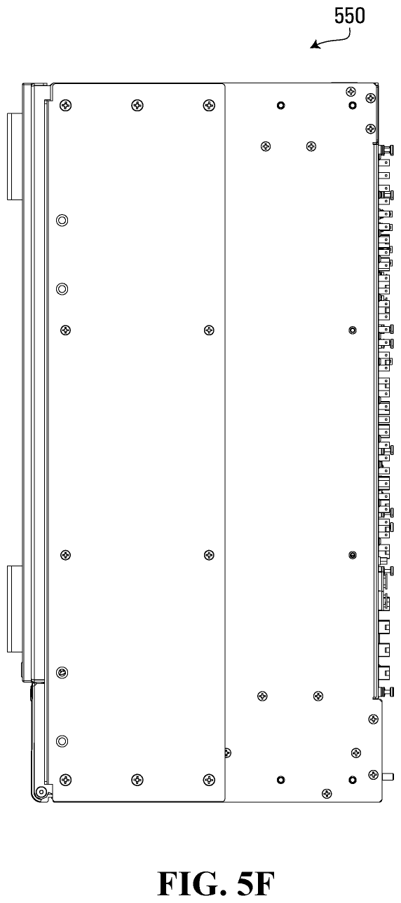

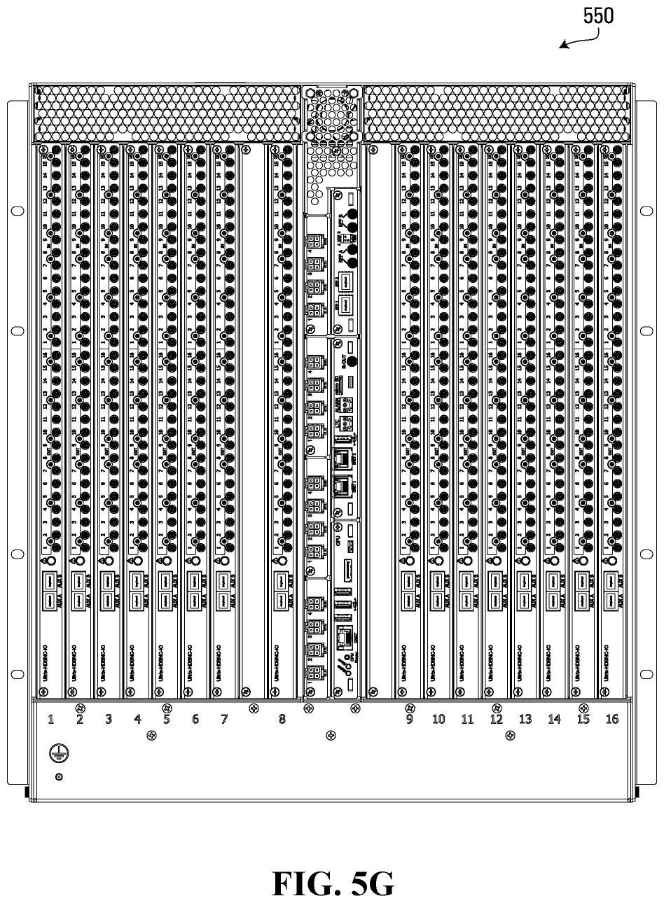

FIGS. 5A and 5B are isometric views of an example video equipment rack-mount chassis 500. FIGS. 5A and 5B are rear and front isometric views, respectively, relative to how the rack-mount chassis 500 would be oriented when installed in an equipment rack. The rack-mount chassis 500 includes a housing or enclosure with a top panel 510, side panels 514, 516, and a bottom panel (not shown). These panels may be separate panels that are coupled or fastened together as shown, or multiple panels may be integrated together. A panel 512 at the front of the rack-mount chassis 500, although oriented toward the front of an equipment rack when the rack-mount chassis 500 is installed, may be the backplane 204 in FIG. 2, for example.

When the rack-mount chassis 500 is assembled, it may be open at the side facing the rear in the view shown in FIG. 5A. The opposite side of the housing would also be open, if not for the front panel 512. As noted above, this panel 512 may be the rack-mount chassis backplane, in which case the backplane, in effect, covers an opening in the housing even though it is not only a structural panel of the housing. Similarly, the opposite opening at the rear of the rack-mount chassis could be covered by other components as well, such as a cover plate 560 of a video card and other cover plates 570, which could be installed to cover card openings in a rack-mount chassis housing when no cards are installed in one or more available card slots provided in a backplane. In the example shown in FIG. 5B, there are openings for four cards and a backplane would include four card slots (not shown), but only one card is actually installed.

The brackets 502 at each side of the example rack-mount chassis 500 enable the rack-mount chassis to be installed and retained in an equipment rack, using fasteners such as screws or bolts that pass through the bores 504 and into bores in an equipment rack. Fasteners are commonly used to install or mount a rack-mount chassis in an equipment rack, but other retention means may also or instead be used. The side or face of the rack-mount chassis 500 at the panel 512 in FIG. 5A may be referred to as a front side or face, because that side or face would be facing out of an equipment rack (i.e., at a front of the equipment rack) when the rack-mount chassis is mounted to the equipment rack. In other words, this side or face may be considered an external face of the rack-mount chassis 500 at which the rack-mount chassis is mounted, or is to be mounted, in or to an equipment rack. It is this side or face for which, in accordance with embodiments disclosed herein, a cover is provided.

FIGS. 5A and 5B illustrate one example rack-mount chassis 500. Variations are possible. For example, video cards need not be oriented horizontally as shown in FIG. 5B. Vertically oriented cards are also contemplated. Fans 520, shown by way of example in the side panel 514 in FIG. 5A, are also optional.

FIGS. 5C-5G include front, left, top, right, and rear views of an example video equipment rack-mount chassis according to an embodiment. The rack-mount chassis 550 provides a housing or enclosure for video cards, and the top, side, and bottom housing or enclosure panels may be separate panels that are coupled or fastened together or integrated together. A panel at the front of the rack-mount chassis 550, behind the cover in the view shown in FIG. 5C, may be a backplane similar to the backplane 204 in FIG. 2, for example.

A noted at least above for the embodiments in FIGS. 5A and 5B, when the rack-mount chassis 550 is assembled, it may be open at the side facing the rear in the view shown in FIG. 5C. The front side of the housing may also be open, if not for the cover, and possibly a panel behind the cover in some embodiments. The opening at the rear of the rack-mount chassis 550 could be covered by a cover plate of a video card or other cover plates, such as shown at 560, 570 in FIG. 5B, which could be installed to cover card openings in a rack-mount chassis housing when no cards are installed in one or more available card slots.

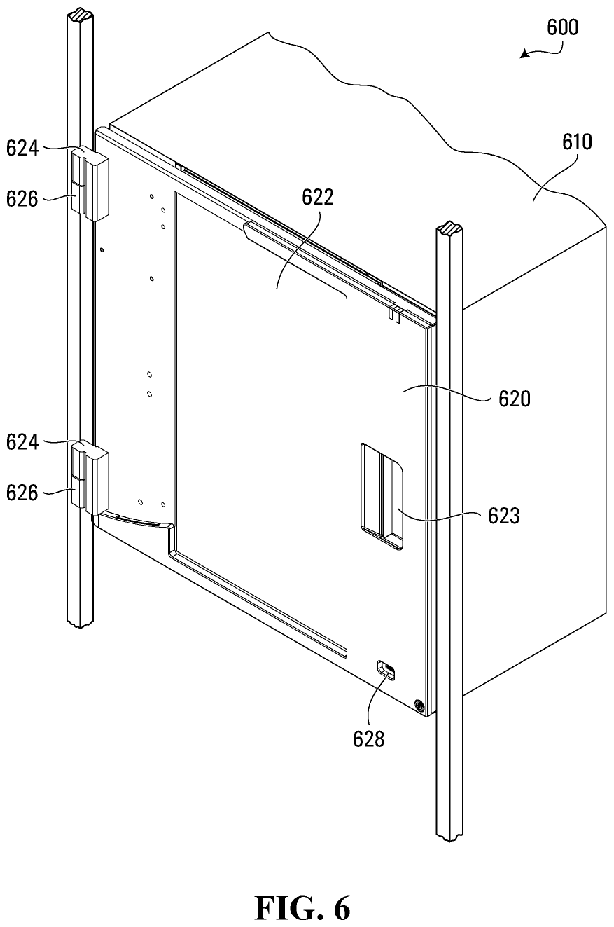

The brackets 552 at each side of the example rack-mount chassis 550 enable the rack-mount chassis to be installed and retained in an equipment rack, using fasteners such as screws or bolts that pass through the bores 554 and into bores in an equipment rack. Other retention means may also or instead be used to mount the rack-mount chassis 550 to an equipment rack. The side or face of the rack-mount chassis 550 at the front in the view shown in FIG. 5C would be facing out of an equipment rack (i.e., at a front of the equipment rack) when the rack-mount chassis is mounted to the equipment rack. This is perhaps most clearly shown in FIG. 6, described below. The front side or face is an external face of the rack-mount chassis 550 at which the rack-mount chassis is mounted, or is to be mounted, in or to an equipment rack, and in accordance with embodiments disclosed herein a cover is provided for that external face.

FIGS. 5A and 5B illustrate a rack-mount chassis 500 with horizontally oriented electronic cards, and the rack-mount chassis 550 provides an example of a rack-mount chassis with vertically oriented electronic cards as shown most clearly in FIG. 5G.

The examples provided above are intended to illustrate video equipment installations in which, or in conjunction with which, embodiments may be implemented.

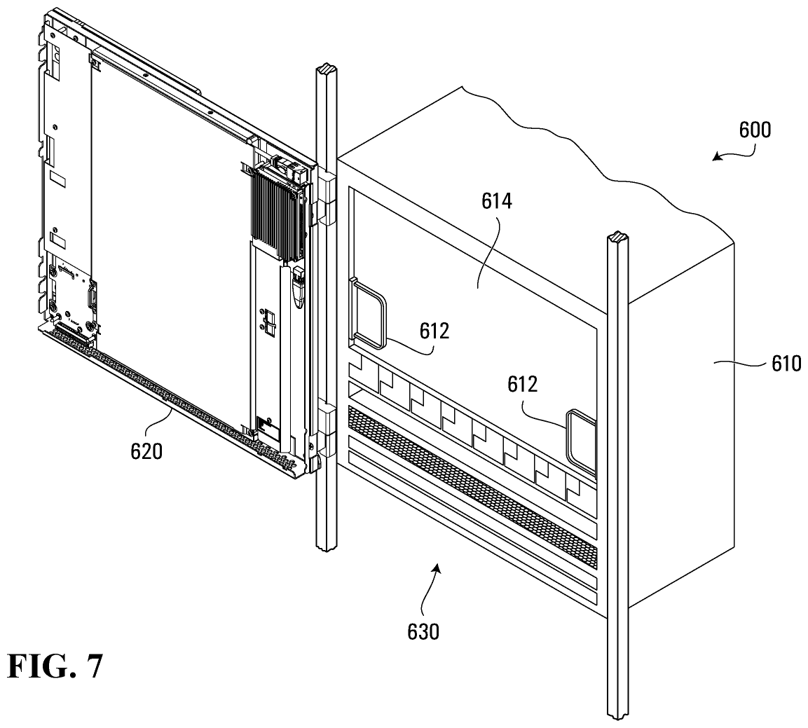

FIG. 6 illustrates an example of a video equipment rack-mount chassis with a front cover according to one embodiment, mounted in an equipment rack, and FIG. 7 illustrates the example video equipment rack-mount chassis in FIG. 6 with the front cover open.

The rack-mount chassis in FIGS. 6 and 7 is shown in a mounted position, and for illustrative purposes an equipment rack is also partially shown in FIGS. 6 and 7. It should be noted, however, that a rack-mount chassis is not intended to be limited only to a chassis that is directly mounted in an equipment rack. For example, a rack-mount chassis with a cover as disclosed herein may be mountable to or installed in an equipment rack, and this may be a common implementation or deployment scenario. It is also possible that a rack-mount chassis may be mountable to another component, which in turn is mounted or mountable to an equipment rack, for example.

FIGS. 6 and 7, and other examples herein, are illustrative of video processing equipment that includes a rack-mount chassis that is mountable to an equipment rack. In the example video processing equipment 600, the rack-mount chassis 610 provides a housing or enclosure to accommodate at least video cards that support processing of video input signals to generate video output signals. There may be other types of input signals and/or output signals, but video processing equipment handles at least video signals or other types of signals related to video, examples of which are provided elsewhere herein. The relationship between input and output signals is implementation-dependent, and in particular depends on the type(s) of processing, such as video/audio routing for example, provided or supported by video cards.

The example video processing equipment 600 also includes a cover 620 for an external face of the rack-mount chassis at which the rack-mount chassis is mountable to the equipment rack. The external face is behind the cover 620 in FIG. 6, but visible at 630 in FIG. 7. A cover as disclosed herein may, but need not necessarily, completely cover the entire extent of an external face of a rack-mount chassis. In the example of FIG. 6 the external face is behind the cover 620, but this is just one embodiment. As shown by way of example in FIG. 5C, a cover need not completely cover the external face of a rack-mount chassis. A face or surface of a chassis may extend beyond a bottom of a cover as shown at 551 in FIG. 5C, or otherwise not be completed covered by a cover. An external face may be partially or completely covered.

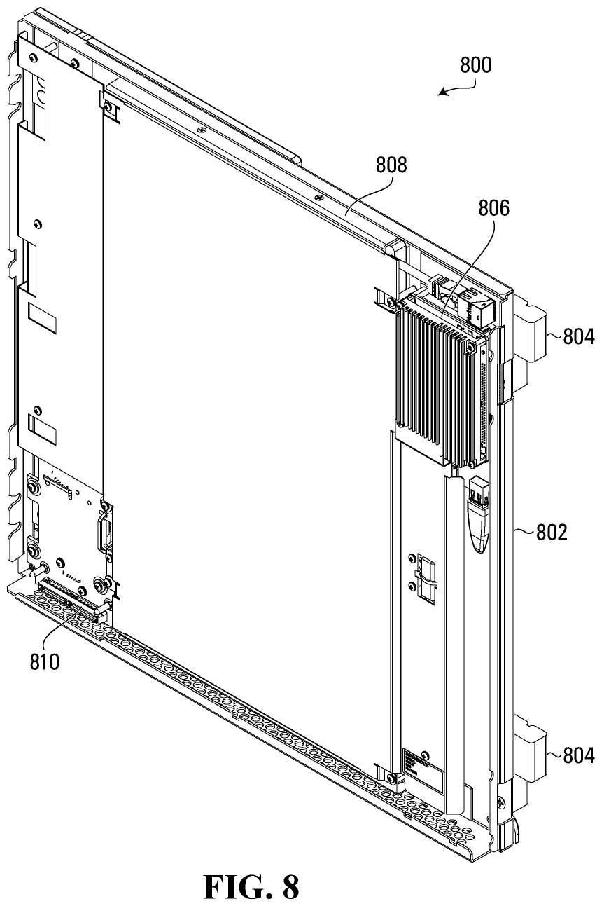

The cover 620 includes a control unit, a connector to provide a local connection between the control unit and video cards installed in the rack-mount chassis, and a display 622. The control unit and connector are described in further by way of example below, with reference to FIG. 8. The display 622 is coupled to the control unit to provide a control interface that enables control of the video processing equipment by an operator.

Video processing equipment may be provided in any of various forms. For example, video cards may, but need not necessarily, be installed in or otherwise provided with a rack-mount chassis. Video cards would have been installed in the housing of a rack-mount chassis when video processing equipment is deployed and ready for operation. It is therefore possible that a rack-mount chassis may be provided with video cards installed and ready for deployment. In other embodiments, a rack-mount chassis may be provided without video cards having first been installed. Video cards may be provided with but not installed in a rack-mount chassis, or provided separately and later installed in a rack-mount chassis when the chassis is to be deployed.

A rack-mount chassis may also or instead be provided without a cover. A cover may be a separate item or component, and may be mounted to, provided with but not mounted to, or provided separately from a rack-mount chassis.

In some embodiments, a rack-mount chassis includes a backplane for connection to video cards, and in such embodiments the local connection between the control unit and the video cards may be or include a connection between the backplane and the control unit. This type of local connection, which is a more direct connection to video cards than a network connection, provides significant benefits as discussed in detail elsewhere herein.

As described herein, a cover such as the cover 620 may be provided for an external face of a rack-mount chassis. That external face may be or include a backplane in some embodiments. With reference to FIG. 5C as an example, a backplane may be behind the cover 550, and in FIG. 7 the cover 620, when closed, covers the backplane 614.

A cover may be mounted or mountable to a rack-mount chassis and/or to an equipment rack. With reference to FIGS. 6 and 7, for example, the cover 620 is movable to uncover the external face of the rack-mount chassis 600 that is covered when the cover is closed. In the embodiment shown, the cover 620 is mounted by a pair of multi-part hinges. One part 624 of each hinge is mounted to the cover 620, and another part 626 of each hinge is mounted to the equipment rack. The parts of each hinge may include a mountable portion such as a plate portion and cooperating engaging portions that are intended to engage each other, such as a hinge pin attached to one plate portion and a hinge barrel attached to the other plate portion to receive the hinge pin.

As is perhaps most clearly shown in FIG. 5C, hinges may be mountable to a bracket 552 of a rack-mount chassis. More generally, a hinge or other hardware may be mountable to a bracket or to another part of a rack-mount chassis, to an equipment rack, or possibly to both a rack-mount chassis and an equipment rack. In the context of a rack-mount chassis that has been mounted to or in an equipment rack, for example, hardware that is mounted to the rack-mount chassis may also or instead be considered to be mounted (indirectly) to the equipment rack.

A hinge is one example of mounting or attachment hardware by which a cover may be retained in place to cover an external face of a rack-mount chassis. The present disclosure is not in any way limited to hinges. Other types of mounting or attachment hardware or features, that allow a cover to be retained in place and move or removed entirely to uncover an external face of a rack-mount chassis, are possible.

As noted at least above, a rack-mount chassis may be provided with or without having a cover installed. A cover may be provided separately from a rack-mount chassis, including as a retrofit or upgrade for a rack-mount chassis. For example, a cover that is mountable to an equipment rack may be mountable at one side of a rack-mount chassis, by one or more hinges for example, and moved to cover and uncover an external face of the rack-mount chassis. In some embodiments, a rack-mount chassis may be designed or modified for use with a cover. In FIG. 7, foldable handles 612 are provided to facilitate installation and removal of the rack-mount chassis, and can be folded when not in use. An existing rack-mount chassis may be modified to remove existing fixed handles, or to replace fixed handles with foldable handles, to enable the rack-mount chassis to be used with a cover.

FIG. 8 is a block diagram illustrating an example cover according to an embodiment. The example cover 800 is in the form of a door, and FIG. 8 is intended to represent a view from the rear of the cover, which would be on the inside of the cover, facing the rack-mount chassis, when the cover is in place to cover an external face of the rack-mount chassis. The cover 800 includes a frame 802 that is mountable to a rack-mount chassis, or to an equipment rack, with one or more hinges 804. Two hinges are shown, but there may be more or fewer hinges, or different mounting hardware, in other embodiments. One or more hinges 804 enable the cover 800 to be pivoted to cover and uncover an external face of a rack-mount chassis. A cover may be movable in other ways in other embodiments, where different mounting hardware is provided instead of hinges 804. As noted at least above other types of mounting hardware are possible.

The frame 802 may be made primarily from or include metal or plastic, for example, or any other material(s) of sufficient strength to carry other cover components. The other cover components in the example shown include a control unit 806, a display 808, and a connector 810. At least the control unit 806 and the display 808 are integrated into the cover 800, and in particular the frame 802 in the example shown. The control unit 806 and the display 808 are integrated in the sense that they are entirely, or at least substantially, positioned within the cover 800 such that they move with the cover and in effect are parts of the cover. The connector 810 is similarly, at least partially, integrated with the cover 800. Depending on the connector type, the connector 810 may include a short cable or other conductor to couple the control unit 806 to a connector on or in a rack-mount chassis, and in that sense a connector might not be integrated into a cover to quite the same degree as a control unit or a display.

The hinges 804 in the example shown, or more generally mounting hardware for mounting a cover to a rack-mount chassis or an equipment rack, may similarly be made from or include metal, plastic, or any other material(s) of sufficient strength to carry the cover 800.

In general, hardware, firmware, components which execute software, or some combination thereof might be used in implementing at least the control unit 806. Electronic devices that might be suitable for implementing the control unit 806 include, among others, microprocessors, microcontrollers, Programmable Logic Devices (PLDs), Field Programmable Gate Arrays (FPGAs), Application Specific Integrated Circuits (ASICs), other types of “intelligent” integrated circuits, and multiples and/or combinations of any of these.

Regarding the display 808, any of various types of display devices may be implemented in the cover 800. Touchscreen displays may be particularly preferred in order to not only provide outputs to an operator but also receive inputs from an operator, thereby providing a more fully functional control interface for an operator.

The specific components and physical arrangement of components shown in FIG. 8 are intended as non-limiting examples. As an example, one display 808 is shown, but more than one display may be provided in other embodiments. Other components may also or instead be provided, such as an external connector shown by way of example at 628 in FIG. 6, one or speakers to provide audio output to an operator, one or microphones to accept audio input from an operator, physical ports or elements to provide wired and/or wireless connections to peripherals such as audio visual (AV) or human interface (HI) peripherals such as a keyboard or external pointing device (a mouse for example), etc.

Cover components may also be laid out in any preferred manner. A connector, for example, may be located closer to a control unit in order to shorten connection length, or closer to hinges to potentially allow the control unit to remain connected to a rack-mount chassis when a cover is open or otherwise moved to uncover an external face of the rack-mount chassis. To at least some extent, placement of cover components may be determined based on esthetic appeal, to position a display centrally on a cover, for example.

Some embodiments may also or instead include different components than those shown. As an example, a hinged cover may include a closure to keep the cover closed unless opened by an operator. A magnetic or mechanical closure may serve this purpose. Other locking or mechanical means of keeping a cover closed unless intentionally opened by an operator are also possible.

A means to prevent a cover from being removed, such as a screw or a locking mechanism that prevents hinge parts from being separated and the cover being removed from a rack-mount chassis or equipment frame, for example, may also or instead be provided.

A cover may also or instead include one or more handles to assist an operator with moving the cover. No handles are shown in FIG. 8 in order to avoid further congestion in the drawing, but a handle is shown by way of example at 623 in FIG. 6.

Although a cover is also shown by way of example in FIGS. 5C, 6, and 7, FIG. 8 perhaps more clearly illustrates that a cover may be provided separately from a rack-mount chassis. Such a cover may be designed as a cover for an external face of a rack-mount chassis for video processing equipment, but need not necessarily be installed or mounted on, or even packaged with, a rack-mount chassis. The external face for which the cover is provided is a face at which the rack-mount chassis is mountable to an equipment rack.

As in other embodiments, a cover may include an integrated control unit such as 806, a connector such as 810 to provide a local connection between the control unit and video cards of the rack-mount chassis that support processing of video input signals to generate video output signals, and an integrated display such as 808, which is coupled to the control unit to provide a control interface. The control interface enables control of the video processing equipment by an operator.

In embodiments in which the rack-mount chassis includes a backplane for connection to the video cards, the local connection may be or include a connection between the backplane and the control unit. The external face may be or include the backplane when a backplane is provided.

A cover, whether provided with a rack-mount chassis or separately, may be mountable to the rack-mount chassis or to the equipment rack.

In some embodiments, a cover is movable to uncover and/or cover the external face of the rack-mount chassis. A fixed cover is also possible, but a movable cover may be preferred to provide easier access into a rack-mount chassis.

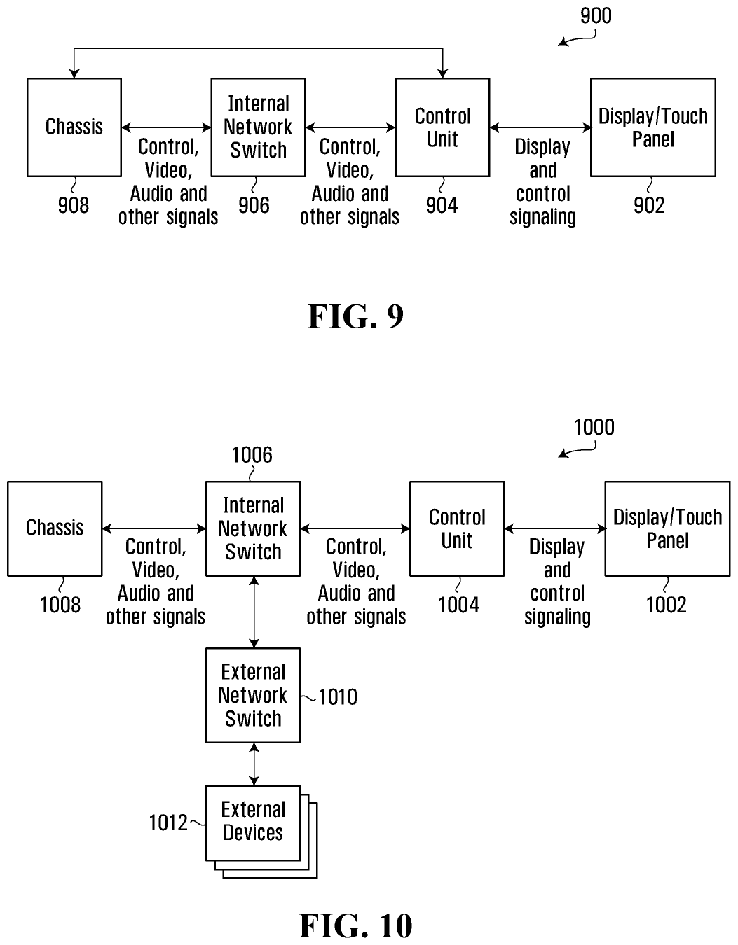

FIGS. 6 to 8 provide relatively detailed examples of a rack-mount chassis and a cover. FIG. 9 is a block diagram illustrating, more generally, an example rack-mount chassis.

The example 900 includes both chassis components and cover components. The cover components provide an integrated workstation, and include a touchscreen display panel 902 and a control unit 904, examples of which are provided elsewhere herein, and connections between the control unit and the chassis components. These connections are provided via one or more cover connectors (not shown) and may provide power, network access, and/or other connections or signals that may be controlled or monitored. These signals may include audio, video, or other signal types available from the chassis, which can eliminate or at the very least reduce extra space required and external connectivity required to attach an external workstation.

The chassis components in the example shown include an internal “network” switch 906 and other components of the chassis that are shown generally at 908 and include at least video cards. The internal switch 906 may be considered a network switch in the sense that it provides connectivity to an internal connection network of the chassis, and may connect the control unit 904 to a control unit and/or other components of the chassis 908. It should be noted that a switch such as 906 need not be provided in all embodiments, and a control unit 904 need not connect to a chassis through a switch or any other separate component.

The internal connection network of a chassis may be constrained to connect to components or devices only within the chassis, so that an integrated control unit of a cover may provide, with the display 902, a control interface that enables local control and monitoring. A cover connector or local connection may also enable connection of an integrated control unit to an external device that is external to a rack-mount chassis. For example, in some embodiments, signals or internal connections may be routed to and from outside of the chassis to permit connection to devices that are outside of the chassis.

FIG. 10 is a block diagram illustrating an example rack-mount chassis that is also operable with one or more external devices. The components at 1002, 1004, 1006, 1008 in the example 1000 may be the same or substantially the same as the similarly-labelled components in FIG. 9. In FIG. 10, the external network switch 1010 enables connection to one or more external devices 1012 via external connections that are not within the chassis 1008. These external connections may be through one or more network interfaces or other interfaces, and the external devices 1012 may include devices in different rack-mount chassis, different equipment racks, or even different premises.

From a technology standpoint, local connection to a chassis demonstrates additional innovation in taking advantage of direct access to internal chassis connections, in an FPGA-based routing architecture and video processing platform for example, to integrate a client-workstation grade control surface or interface. Local connections may be considered direct in the sense that such connections are not network connections and avoid, for example, latency associated with such connections. The extremely low latency of a local connection compared to latency of a network connection is an important advantage, and a further advantage of a local connection over a network connection is not requiring consumption of any network bandwidth to pass signals between a chassis and another system. Even in the case of connections to external devices as in FIG. 10, these and other potential advantages of local connections can be realized at least in respect of local connections between a control unit 1004 and chassis components 1008.

A control interface as referenced herein is not necessarily restricted only to control features. For example, a control interface that is provided by an integrated display and a locally connected control unit may further enable any of various features or functions, such as any one or more of: monitoring, diagnostics, and configuration, of any of various components or signals such as video cards, other electronic cards, a chassis or specific parts thereof, video processing equipment, input signals, and output signals. These and/or other features or functions may also or instead be enabled for external devices in an embodiment as shown in FIG. 10, for example.

A local control interface that is fully-functional or nearly fully-functional as an operator workstation may provide or support the ability to monitor, analyze, and/or debug, “live” and in real time, by presenting actual media essences at a touch, with significantly reduced or zero latency or bandwidth consumption. A local connection in a chassis (to a backplane in some embodiments) means direct and local access to media essence streams (audio/video/metadata). Any of status, analysis, diagnostics, and local video displays may be presented directly on a chassis or equipment rack, and a cover as disclosed herein can also provide associated processing/diagnostic components, features, and functions.

Direct signal paths to a chassis via local, direct connectivity is an enabler for a wide variety of applications, including direct signal monitoring, signal quality analysis, internal frame analytics, and/or others. Illustrative examples of various potential applications or features are provided herein, and others may be or become apparent based on the present disclosure.

These local connection, control interface, and direct signal path features are illustrative of key advantages and technical innovations embodied in the present disclosure.

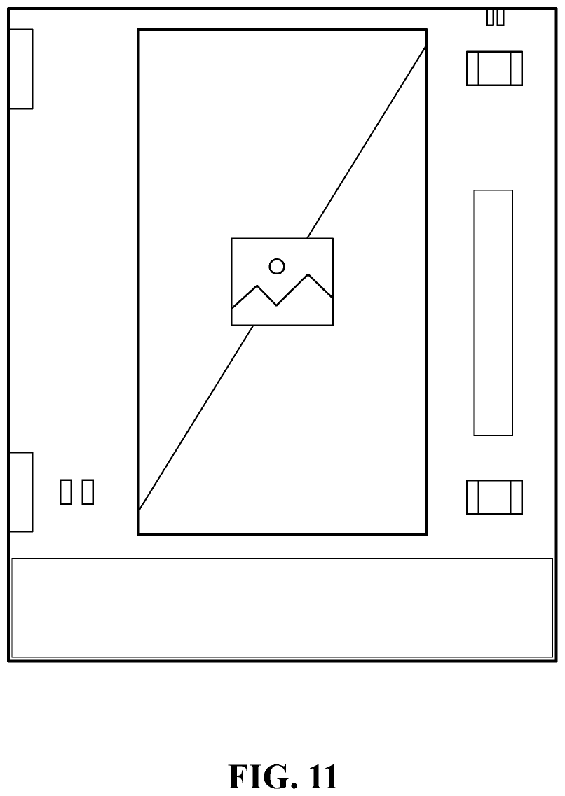

FIGS. 11-19 are representations of example Graphical User Interface (GUI) screens that may be presented on a cover display in some embodiments.

FIG. 11 includes a sample representation of an integrated workstation display screen and is intended to illustrate such a display showing video. The displayed video may be a video input or output signal of video processing equipment, or a screen-saver type video or image may be presented when the integrated workstation is not in use.

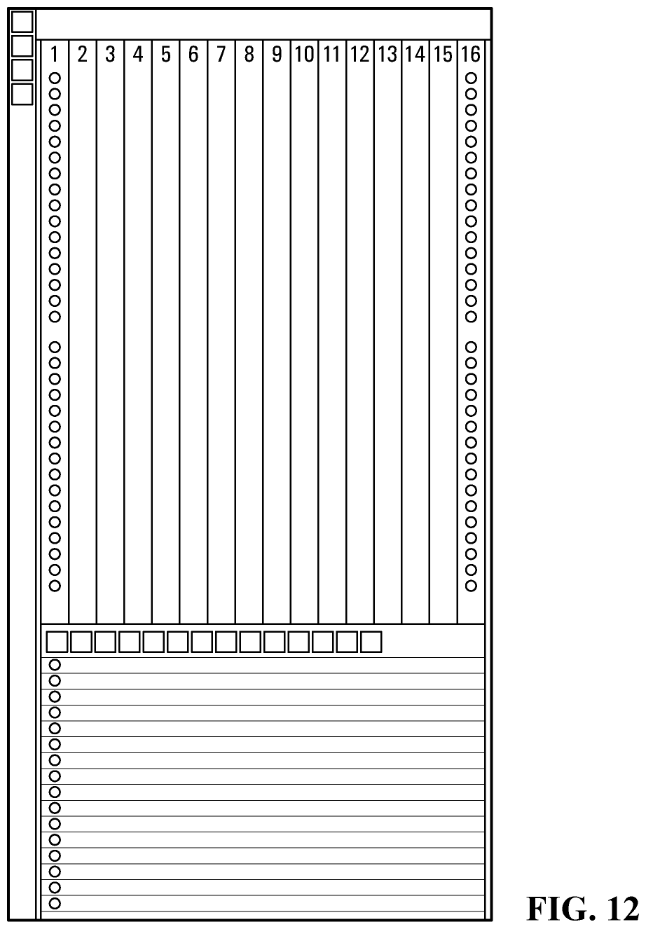

FIG. 12 includes a sample representation of a diagnostic/monitoring/“health” display screen, depicting rack-mount chassis inventory and signal status for up to sixteen input ports and sixteen output ports of each of up to sixteen video cards installed in sixteen available slots. The circles shown at the top in FIG. 12 may be displayed in different colors depending on status of each of the sixteen input ports and sixteen output ports in each of sixteen cards, and the circles shown at the bottom in FIG. 12 may similarly provide different colors as indicators of different signal status related to a card slot that is selected, in the upper part of FIG. 12 for example.

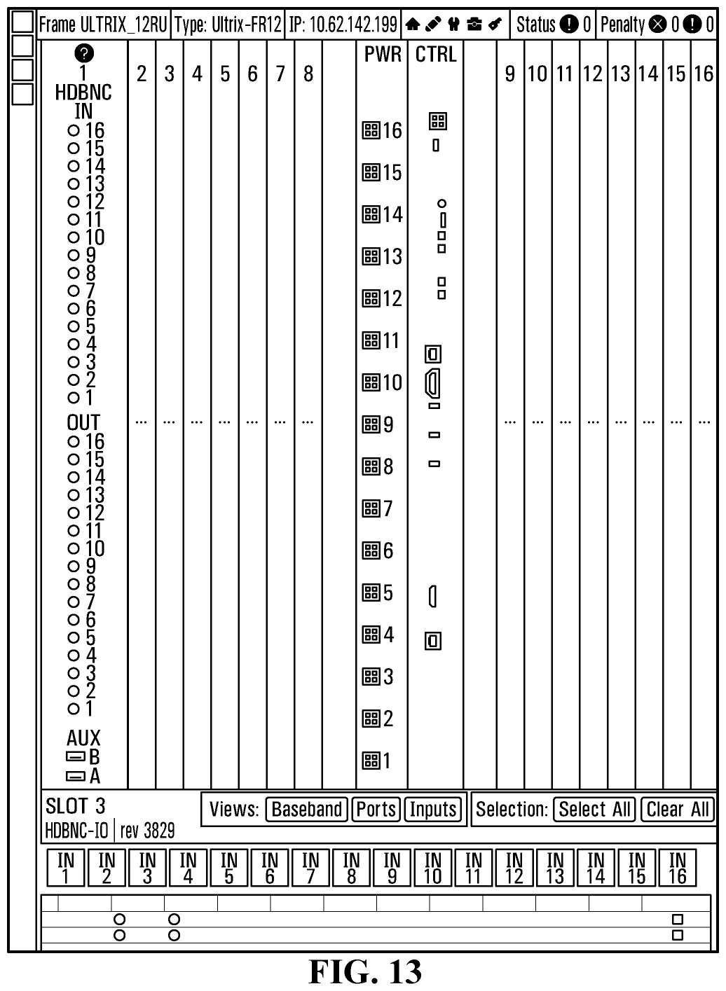

FIG. 13 shows a more detailed example similar to FIG. 12. Signal status indicators for the first card slot are shown for card slot 1, but may be provided for each card slot. All such indicators are not shown in the drawing due to space limitations. In FIG. 13, slot 3 is selected as indicated to the left, below the auxiliary (AUX) ports A and B for the first card slot. A card slot (slot 3 in this example) may be selected at the top in FIG. 13. Other section options, and view options, are shown to the right of the selected slot 3 indicator in FIG. 13.

Power and control indicators are shown in the middle of the card slot input and output indicators at the top in FIG. 13.

The lower part of FIG. 13 may include indications of various information for each of the sixteen inputs of the selected slot in the example shown. For example, there may be sixteen lines below the “IN” indicators at the bottom in FIG. 13, although only two are shown due to space limitations.

Information about the inputs (or ports) for a selected slot (or card in a selected slot) may include, for example, any one or more of the following for each input or port:
input or port group information such as a group number;
input or port physical address such as slot number and/or input or port number;
video format for each input or port, such as 1080i 59.94 as one example (next to a first circular “present” indicator in each row, which may be displayed in different colors to indicate that a video signal is or is not present, for example);
audio signal type such as “PCM” for pulse-code modulation as an example (next to a second circular “present” indicator in each row, which may be displayed in different colors to indicate that an audio signal is or is not present, for example);
one or more types of frame timing information;
frame synchronization information;

Loss of signal (LoS) behavior such as “Black” for display of a black screen under an LoS condition.

Input or port information may also or instead include configurable information or settings, indicated by the blocks in the last columns of the two bottom rows in FIG. 13. These blocks are intended to represent checkboxes as an example of a graphical control element that is selectable by a user for a user-configurable setting, to turn on and off “Audio Bypass” as an example.

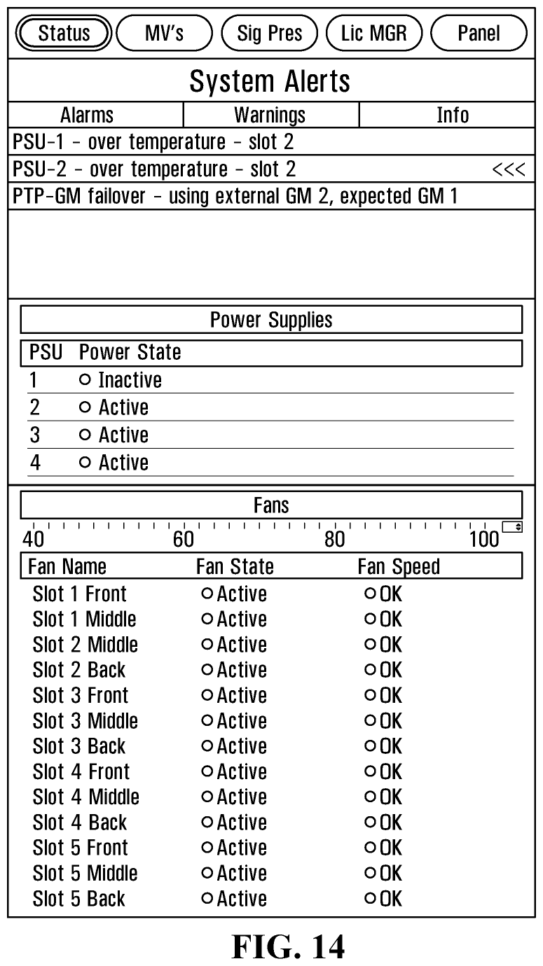

FIG. 14 is another example, of a status screen with power supply indicators (at the middle, labelled “Power Supplies”, and circular indicators in the example shown, which may be displayed with different colors for different power supply status for example, such as PSU1 with a different color and status than the others in this example) and fan indicators (at the bottom, labelled “Fans”, and circular indicators in the example shown, which may be displayed with different colors for different fan status and speed, but all with the same status and color in this example), and alarm/warning summary indicators that may be displayed in different colors and text at the top. In the example shown, there are no information messages at the top, but information messages may be displayed in text and with different background color, for example, than the alarm/warning summary messages.

FIG. 14, and other status screen examples herein, illustrate that a display may provide, in the upper part of a screen for example, a screen or visual output that can highlight status or error conditions for cards, and also or instead, in another part of a screen such as a lower part of the screen, details for one or more cards. This is just one possible type of screen or display output that provides an “on device”, “on-rack”, or “on-chassis” status that can help streamline the work of checking in on video processing equipment locally instead of only from a remote or separate workstation.

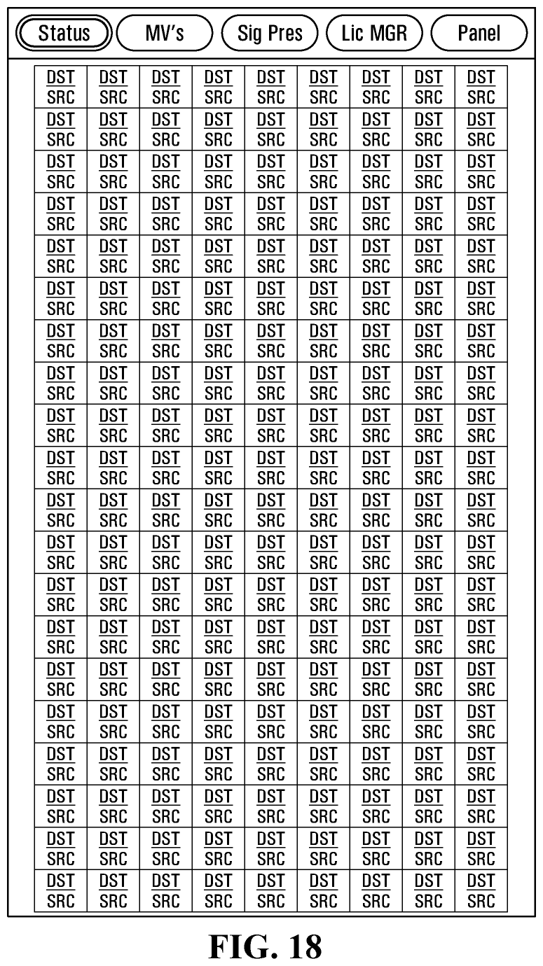

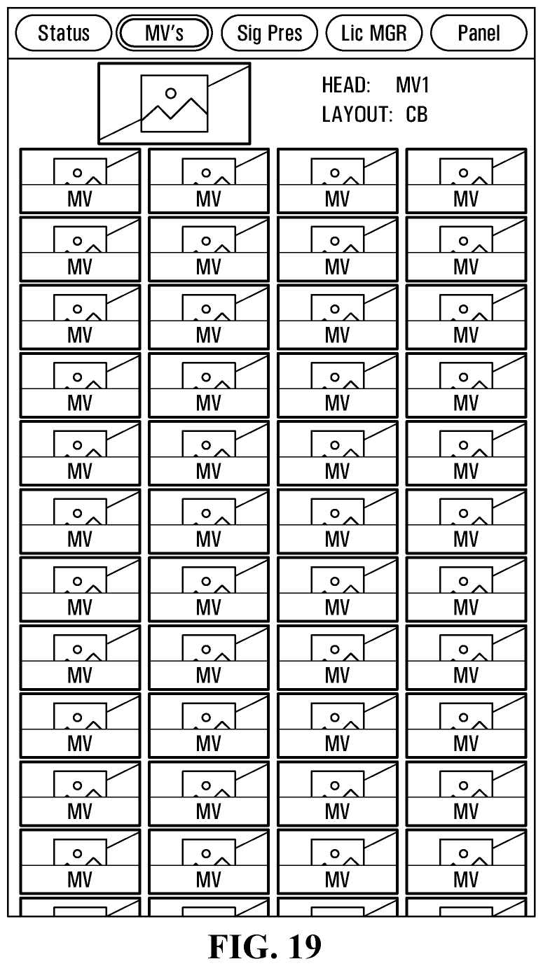

Other graphical control elements for selecting different types of displays are also shown at the top of FIG. 14. Like the “Status” element, these are illustrative examples, any of which may be provided or supported in embodiments. The examples in FIG. 14 include the following:
a “Status” element, selected in FIG. 14 for proving the status display as described;
an “MV” element—“MV” is short for “Multi Viewers” which are composite displays that show multiple video images in a single video feed (multiple pictures-within-a-picture sometimes referred to as “PIPs”), and more detail provided at least below with reference to FIG. 19;
a “Sig Pres” element—“Sig Pres” is short for “signal presence” and is selectable to recall a display mode that summarizes signal presence indicators for input and/or output signals;
a “Lic Mgr” element—“Lic Mgr” is short for “license manager,” which could provide a summary view of features that are enabled by software license keys installed to chassis-such a summary view could provide a depiction of the potential use of a cover as disclosed herein, as a means of displaying and/or configuring options for a router frame for example;
a “Panel” element, which may be selectable to display a window that could allow routing of sources to destinations, for example, in a view similar to the view provided in FIG. 18 but with separate source and destination buttons.

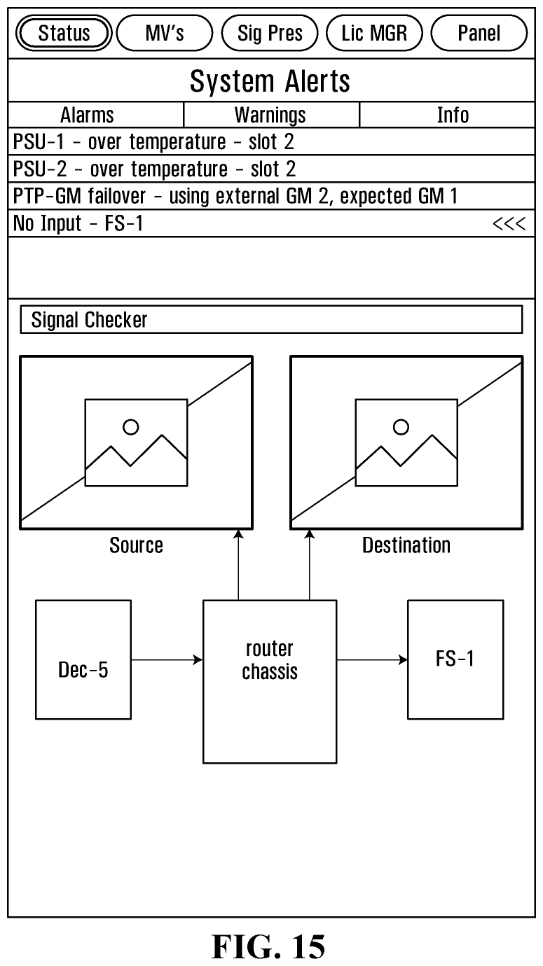

FIG. 15 is another example of a screen with a status summary and video signal monitoring. Source and destination video signals are presented in the example screen as shown, with a representation of a video router chassis that provides or supports a routing matrix at the bottom for an application to video routing. This drawing shows the signal flow “path” used for a selected source and destination. “Dec 5” indicates a satellite decoder and a source mnemonic label that a user configured to refer to the source incoming to the router chassis, which in this example arrives from a satellite feed. “FS1” is another example of a mnemonic label for a destination to which the router chassis has connected the source feed. “FS” in “FS1” refers to a “Frame Synchronizer”—which a user would employ to synchronize timing of the incoming satellite feed signal in this example with other video signals.

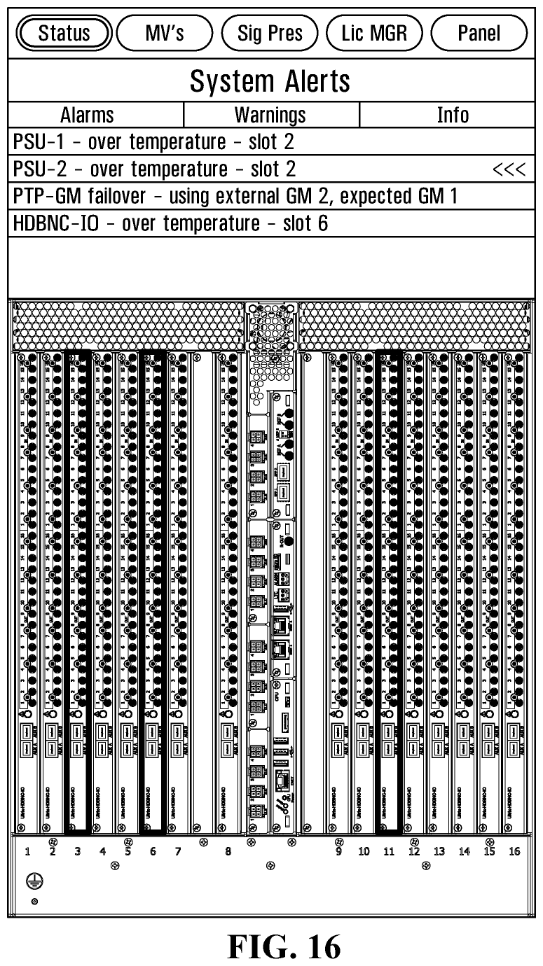

Yet another example is provided in FIG. 16, which is a screen that includes a chassis status summary with video card state indicators, which may be in different colors for example, for different card states. At the top, FIG. 16 is otherwise similar to FIG. 14, but with one additional warning summary message. FIG. 16 is another example of a “Status” option.

For illustrative purposes, the lower part of FIG. 16 shows representations of installed cards as they would be seen if an operator were to view the installed cards from behind a chassis, as in FIG. 5G for example. This feature can be very useful to an operator, in that order and orientation in the screen view matches the order and orientation that an operator would see. In the example shown, three of the card representations (for slots 3, 6, and 11) are outlined, to indicate highlighting of those card representations in a different color from the others, as an example of a video card state indicator to indicate different video card state of those cards. Different outline colors may be used, for example, to indicate that the card is in a “good” state (green, for example) with no detected alarms or warnings, or in a different state (yellow, for example) if there are detected problems (such as unexpected format for some signals) or errors (such as the card being over a temperature target or limit or having no signals).

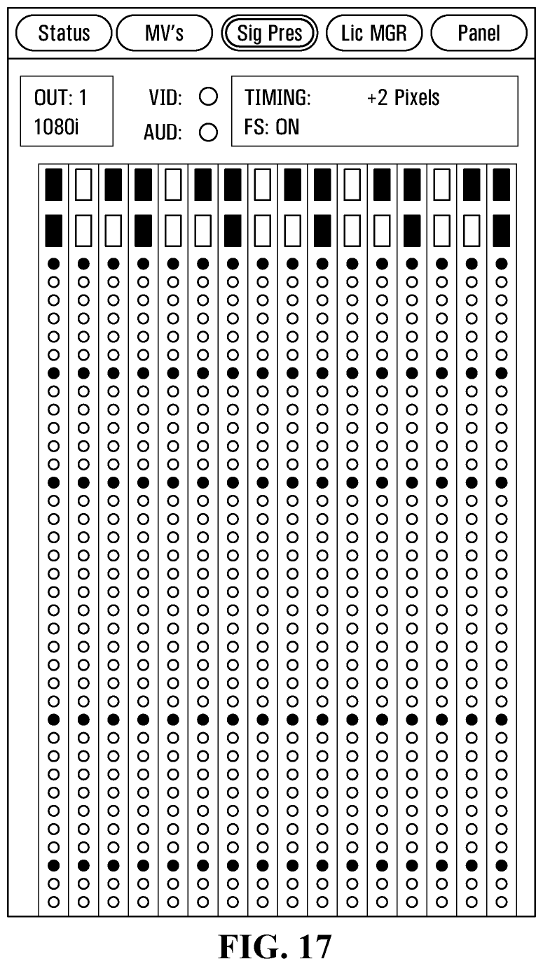

The further example in FIG. 17 relates to a screen showing video signal information with state indicators, in different colors for example, for different states of individual video input and output ports. In the “Sig Pres” example shown, the view depicts signal presence and recalls a display mode that summarizes the signal presence indicators for input and/or output signals. In the example shown, different colors in the indicators may be used to highlight presence or absence of input signal entering a frame and/or output signals leaving a frame. In FIG. 17, the “rectangular” ports indicators toward the top may represent small form-factor pluggable (SFP) or Ethernet connections, and the round indicators may represent status for coaxial (bnc-type) ports on input/output cards within a chassis.

FIG. 18 illustrates an example integrated control surface or interface, which may be configured and used to control physical input and output ports of cards that are installed in a chassis. FIG. 18 provides another example of a status window or screen, which is intended to allow display of crosspoint routing, or in other words the source routed to each of the destinations. The “DST” labels each indicate a destination, and the “SRC” labels each indicate a source that is routed to each destination. Due to space limitations, the general “DST” and “SRC” labels are shown in FIG. 18, but other options are possible, for example to display each label with an index such as SRC 1/DST 1, SRC 2/DST 2, SRC 3/DST 3, and so on, to indicate a more specific association. In practice, such labels may be configured or assigned by a user and may be more informative or application-specific (SAT Rx, STUDIO, CLIP 1, CAM LEFT, MON A, for example) rather than an “indexed” source/destination list or array.

FIG. 19 provides an example of a screen showing a composite “multiviewer” (MV's) display of multiple signals, which may include input and/or output signals, simultaneously. In FIG. 19, “MV” is short for “Multi Viewers”, as above. The MV option in this example may recall displays showing the configuration or video from one or more multiviewer displays. The “Layout” indication at the top in FIG. 19 is a status element that shows a layout that is active for the selected multiviewer head MV1. The lower “MV” buttons below the Head/Layout section in FIG. 19 are elements that allow selection of the different multiviewers, and may be or include “thumbnail” images of the multiviewer video or a still image of the multiviewer's video and/or layout as shown. The “MV” labels are a general example, and multiviewer head names (such as MV1 as shown in the top layout indicator and labels with an index such as MV 1, MV 2, MV 3, and so on), may be used to indicate a more specific association with a multiviewer head. In practice, labels may be configured or assigned by a user to be more informative or application-specific (ROOM A, STUDIO, EDIT 1, SPORTS, for example) rather than an “indexed” list or array.

The screen examples provided herein are not intended to be exhaustive, but rather to illustrate the notion that an integrated display in a cover could show any of various types of information and/or provide any of various selection or other operator input options. A display screen may provide, for example, any one or more of the following, in addition to or instead of the content illustrated in examples or otherwise disclosed herein: signal quality measurements such as eye pattern, vector scope, diagnostic information such as (but not limited to) detected errors, and other diagnostic indicators (such as presence of metadata, audio and/or other information embedded in video or audio streams). Other useful diagnostic data that may be presented by a display includes any one or more of: internal data (such as CPU load, memory use, temperature, fan speed), and information about network connections (such as percentage of network utilization, connections, graphs of network connected devices etc.).

The present disclosure is not in any way limited to providing or supporting any particular types of inputs or outputs.

Various embodiments are disclosed herein, primarily in the context of video processing equipment, rack-mount chassis, and covers. Other embodiments are also possible.

For example, at least functional features related to video processing, control, configuration, monitoring, analytics, diagnostics, etc., may be embodied as computer-executable or processor-executable instructions stored on one or more non-transitory computer-readable or processor-readable storage media. Such instructions, when executed by one or more computers or one or more processors, cause the computer(s)/processor(s) to perform functions or operations or to support features disclosed herein.

Method embodiments are also possible. For example, a method may involve providing a rack-mount chassis and providing a cover. References to “providing” components are intended to encompass not only manufacturing such components, but also or instead acquiring such components from one or more suppliers or otherwise obtaining or making such components available.

A rack-mount chassis, as in other embodiments herein, is mountable to an equipment rack and includes or provides a housing to accommodate video cards that support processing of video input signals to generate video output signals. A cover is for an external face of the rack-mount chassis at which the rack-mount chassis is mountable to the equipment rack, and includes a control unit, a connector to provide a local connection between the control unit and the video cards, and a display coupled to the control unit to provide a control interface that enables control of the video processing equipment by an operator.

Such a method may also involve providing the video cards, and in some embodiments installing the video cards in the housing.

During assembly or installation of a chassis, for example, a method may involve engaging the connector to complete or otherwise create the local connection, which may be between the control unit and a backplane for connection to the video cards. Engaging a connector may involve any of different types of actions or operations, depending on the type of connector. Such actions or operations may include, for example, closing a hinged cover or otherwise orienting cooperating cover and chassis connectors into operative locations relative to each other, plugging a cover connector into a chassis connector or vice versa, etc.

Providing a cover may involve providing, as the cover, a cover that is mountable to the rack-mount chassis, in which case a method may involve mounting the cover to the rack-mount chassis.

Another example of providing a cover involves providing, as the cover, a cover that is mountable to the equipment rack, in which case a method may involve mounting the cover to the equipment rack.

In some embodiments, providing a cover involves providing, as the cover, a cover that is movable to uncover the external face of the rack-mount chassis. With a movable cover, a method may involve moving the cover to cover and/or uncover the external face of the rack-mount chassis.

Yet another example of providing a cover involves providing, as the cover that includes the connector, a cover that includes a connector that further enables connection of the control unit to an external device that is external to the rack-mount chassis.

As also described elsewhere herein, a control interface may further enable any one or more of: monitoring, diagnostics, and configuration of the video processing equipment, the input signals, and the output signals.

A method need not necessarily involve providing a chassis. For example, another method embodiment involves providing an integrated control unit integrated with a cover for an external face of a video processing equipment rack-mount chassis at which the rack-mount chassis is mountable to an equipment rack; providing a connector to provide a local connection between the control unit and video cards of the rack-mount chassis that support processing of video input signals to generate video output signals; and providing an integrated display integrated with the cover, the display being coupled to the control unit, to provide a control interface that enables control of the video processing equipment by an operator.

Such a method may also involve engaging the connector to create the local connection between the control unit and a backplane for connection to the video cards.

Some embodiments may involve providing, as the cover, a cover that is mountable to the rack-mount chassis (and possibly mounting the cover to the rack-mount chassis) or a cover that is mountable to the equipment rack (and possibly mounting the cover to the equipment rack).

Another example of providing a cover, as also described at least above, is providing a cover that is movable to uncover the external face of the rack-mount chassis. A method may then involve moving the cover to cover and/or uncover the external face of the rack-mount chassis.

Operator usage of a cover may include controlling video processing equipment via the control interface that is provided by a display.

The control interface provided by a display may further enable any one or more of: monitoring, diagnostics, and configuration of the video processing equipment, the input signals, and the output signals. In some embodiments, a method may include performing the enabled one or more of: monitoring, diagnostics, and configuration of the video processing equipment, the input signals, and the output signals via the control interface.

A cover connector may further enable connection of a control unit to an external device that is external to the rack-mount chassis. In such embodiments, a method may involve controlling the external device via the control interface. The control interface may also enable any one or more of: monitoring, diagnostics, and configuration of the external device, in which case a method may involve performing the enabled one or more of: monitoring, diagnostics, and configuration of the external device via the control interface.

Other features disclosed herein may also or instead be provided in method embodiments. More generally, features disclosed herein in the context of any embodiment may be provided in other embodiments.

An integrated control, diagnostic, and monitoring touch panel display for a video routing and/or processing platform, according to embodiments disclosed herein, may provide various benefits for equipment operators.

Eliminating the need for separate monitor and control displays and test equipment, for example, may provide such benefits as:
space savings;
weight savings;
time savings, especially during such tasks as system setup, configuration, and testing;
more efficient diagnostic and troubleshooting workflows during all phases of use of video equipment;
lower latency and less usage of network resources for transferring signals between chassis and operator workstations;
elimination of cost of extra displays for common diagnostic support and operational tasks.

Additional connection cabling may also be eliminated, potentially further reducing:
space;
weight;
materials;
equipment installation time and setup effort;
possibility of cabling and setup errors.

In some embodiments, a cover with a display may provide a local and integrated interface to an operator for:
frame and system control and monitoring;
video monitoring including local or remote video, internet protocol (IP) streams, or multiviewers;
advanced diagnostic tools such as waveforms, error rates, eye patterns, etc. ;
user-configurable custom status or branding displays, and applications;
license management;
management of other items such as any of: software versions, licensed features, device configuration, and/or security posture;
other features such as branding/advertising in either private or public spaces.

Integrated workstation design as disclosed herein may also or instead enable:
execution of control, status, and/or configuration tasks without setting up a client control workstation;
reduced operator time for switching attention between different pieces of equipment because multiple rack-mount chassis or equipment racks may be connected to the same integrated local workstation or each may have its own local workstation available for use;
custom applications and displays tailored to an operator's specific application or preferences;
future video and audio processing/analysis features to promote time and equipment savings.

In some embodiments, diagnostic capabilities may include, for example:
signal analysis and quality measurement tools (e.g., eye pattern, waveform display);
video and audio measurement (e.g., vector scope, audio meters, etc.);
network measurement and/or analysis, with output of measurement and/or analysis results on an integrated display;
integrated multiviewer displays for simultaneous viewing of diagnostic output displays, and/or video for analysis or confidence monitoring;
comparison of signals that may extend to visual difference, waveform comparison or difference, and/or analytical comparison (for example bit error rate (BER), etc.);
local touchscreen display system and control surface to select signals for analysis and/or to configure integrated diagnostic tools;
monitoring and configuration of internal frame components;
monitoring of signal input and/or output parameters;
inventory verification and control of frame options, licenses, and/or other settings.

In some embodiments, what is displayed may be based on a current or previous state of chassis components and data on its inputs, such as when in configuration mode showing configuration specific applications, when a signal is lost or degraded showing that signal and diagnostic applications, or when first powering up showing a selection of applications to choose from or a last application that was running.

What has been described is merely illustrative of the application of principles of embodiments of the invention. Other arrangements and methods can be implemented by those skilled in the art without departing from the scope of the present invention.

For example, the divisions of functions as shown in FIGS. 9 and 10 are intended solely for illustrative purposes. Embodiments may be implemented with fewer, additional, and/or different components than those explicitly shown.

In addition, although described primarily in the context of apparatus, other implementations are also contemplated, in the form of methods and instructions stored on one or more non-transitory computer-readable storage media, for example.

1. Video processing equipment comprising:
a rack-mount chassis that is mountable to an equipment rack, the rack-mount chassis comprising a housing to accommodate a plurality of video cards that support processing of video input signals to generate video output signals;
a cover for an external face of the rack-mount chassis at which the rack-mount chassis is mountable to the equipment rack, the cover comprising a control unit, a connector to provide a local connection between the control unit and the plurality of video cards, and a display coupled to the control unit to provide a control interface that enables control of the video processing equipment by an operator.

2. The video processing equipment of claim 1, further comprising:
the plurality of video cards installed in the housing.

3. (canceled)

4. The video processing equipment of claim 1,
the external face comprising a backplane for connection to the plurality of video cards,
the local connection comprising a connection between the backplane and the control unit.

5. to 6. (canceled)

7. The video processing equipment of claim 1, wherein the cover is movable to uncover the external face of the rack-mount chassis.

8. The video processing equipment of claim 1, wherein the control interface further enables any one or more of: monitoring, diagnostics, and configuration of the video processing equipment, the input signals, and the output signals.

9. The video processing equipment of claim 1, the connector further enabling connection of the control unit to an external device that is external to the rack-mount chassis.

10. A cover for an external face, of a rack-mount chassis for video processing equipment, at which the rack-mount chassis is mountable to an equipment rack, the cover comprising:
an integrated control unit;
a connector to provide a local connection between the integrated control unit and a plurality of video cards of the rack-mount chassis that support processing of video input signals to generate video output signals;
an integrated display, coupled to the integrated control unit, to provide a control interface that enables control of the video processing equipment by an operator.

11. to 12. (canceled)

13. The cover of claim 10, wherein the cover is mountable to the rack-mount chassis.

14. The cover of claim 10, wherein the cover is mountable to the equipment rack.

15. (canceled)

16. The cover of claim 10, wherein the control interface further enables any one or more of: monitoring, diagnostics, and configuration of the video processing equipment, the input signals, and the output signals.

17. (canceled)

18. A method comprising:
providing a rack-mount chassis, for video processing equipment, that is mountable to an equipment rack, the rack-mount chassis comprising a housing to accommodate a plurality of video cards that support processing of video input signals to generate video output signals;
providing a cover for an external face of the rack-mount chassis at which the rack-mount chassis is mountable to the equipment rack, the cover comprising a control unit, a connector to provide a local connection between the control unit and the plurality of video cards, and a display coupled to the control unit to provide a control interface that enables control of the video processing equipment by an operator.

19. The method of claim 18, further comprising:
providing the plurality of video cards; and
installing the plurality of video cards in the housing.

20. (canceled)

21. The method of claim 18, further comprising:
engaging the connector to create the local connection between the control unit and a backplane for connection to the plurality of video cards.

22. The method of claim 18, wherein providing the cover comprises providing, as the cover, a cover that is mountable to the rack-mount chassis.

23. The method of claim 18, further comprising:
mounting the cover to the rack-mount chassis.

24. The method of claim 18, wherein providing the cover comprises providing, as the cover, a cover that is mountable to the equipment rack.

25. The method of claim 18, further comprising:
mounting the cover to the equipment rack.

26. The method of claim 18, wherein providing the cover comprises providing, as the cover, a cover that is movable to uncover the external face of the rack-mount chassis.

27. The method of claim 26, further comprising:
moving the cover to cover and/or uncover the external face of the rack-mount chassis.

28. The method of claim 18, wherein the control interface further enables any one or more of: monitoring, diagnostics, and configuration of the video processing equipment, the input signals, and the output signals.

29. to 44. (canceled)
